(19) United States
(12) Patent Application Publication
(10) Pub. No.: US 2026/0160734 A1
(43) Pub. Date: Jun. 11, 2026

(54) ULTRASONIC TRANSDUCER

(71) Applicant: QISDA CORPORATION, Taoyuan City (TW)

(72) Inventor: FU-SHENG JIANG, Taoyuan City (TW)

(21) Appl. No.: 19/340,809

(22) Filed: Sep. 25, 2025

(30) Foreign Application Priority Data
Dec. 11, 2024 (TW) 113148013

(51) Int. Cl. G01N 29/22; B06B 1/06; G01N 29/24; H10N 30/20

(52) U.S. Cl. CPC G01N 29/221; B06B 1/0644; G01N 29/2437; H10N 30/20; B06B 2201/55; B06B 2201/76

(57) ABSTRACT

An ultrasonic transducer includes an energy conversion layer and an acoustic lens layer. The energy conversion layer has a first surface and a second surface that are opposite to each other. The transducing layer includes a piezoelectric material layer. The piezoelectric material layer has a first groove. The acoustic lens layer is disposed on the first surface. The acoustic lens layer has a curved surface. A first coordinate point is defined at a location on the first surface that corresponds to the first groove, the first coordinate point corresponds to a focal point on the curved surface, and a distance between the first coordinate point and the focal point is equal to an integer multiple of half a wavelength of a center frequency of the ultrasonic wave.

### CROSS-REFERENCE TO RELATED PATENT APPLICATION

This application claims the benefit of priority to Taiwan Patent Application No. 113148013, filed on Dec. 11, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an ultrasonic transducer, and more particularly to an ultrasonic transducer that is capable of improving the sidelobe effect.

### BACKGROUND OF THE DISCLOSURE

An ultrasonic transducer, or an ultrasound probe, is a commonly used medical diagnostic instrument. The ultrasonic transducer transmits an ultrasonic wave with a frequency that is greater than 20,000 Hz through internal piezoelectric elements. When the ultrasonic wave enters a human body and is reflected by various tissues within the body, the ultrasonic transducer receives reflected ultrasonic signals to perform image recognition and object detection.

A conventional ultrasonic transducer tends to produce a sidelobe effect. The sidelobe effect refers to radiation that occurs outside the main beam (also known as the main lobe) of the ultrasonic wave. The sidelobe effect typically forms on both sides of the main beam, and affects the performance of the ultrasonic transducer to result in noise or reflected signals. The sidelobe effect is generated because the emitting surface of the ultrasonic transducer has a certain area, which prevents the ultrasonic wave from achieving an ideal focusing effect, thereby resulting in a non-uniform distribution of ultrasonic energy across the emitting surface.

Therefore, how to overcome the above-mentioned problem through an improvement in structural design has become an important issue to be addressed in the related art.

### SUMMARY OF THE DISCLOSURE

In response to the above-referenced technical inadequacy, the present disclosure provides an ultrasonic transducer, so as to address an issue of the existing ultrasonic transducer producing the sidelobe effect.

In order to solve the above-mentioned problems, one of the technical aspects adopted by the present disclosure is to provide an ultrasonic transducer. The ultrasonic transducer includes an energy conversion layer and an acoustic lens layer. The energy conversion layer has a first surface and a second surface that are opposite to each other. The energy conversion layer includes a piezoelectric material layer. The piezoelectric material layer has a first groove, the first groove extends along a first direction, and the first direction is parallel to a thickness direction of the piezoelectric material layer. The acoustic lens layer is disposed on the first surface. The acoustic lens layer has a curved surface, the curved surface extends along a second direction, and the second direction is parallel to a width direction of the piezoelectric material layer. A first coordinate point is defined at a location on the first surface that corresponds to the first groove. The first coordinate point corresponds to a focal point on the curved surface along the first direction. A distance between the first coordinate point and the focal point is equal to an integer multiple of half a wavelength of a center frequency of the ultrasonic wave.

Therefore, in the ultrasonic transducer provided by the present disclosure, the positions in the piezoelectric material layer corresponding to the regions of the acoustic lens layer having a thickness equal to an integer multiple of half the wavelength of the center frequency are identified, and the piezoelectric material at those positions are removed to form the first grooves. This ensures that no ultrasonic waves are transmitted from those positions into the regions of the acoustic lens layer where the thickness corresponds to the integer multiple of half the wavelength of the center frequency. As a result, the noise can be eliminated, and the sidelobe effect can be suppressed.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an ultrasonic transducer according to the present disclosure;

FIG. 2 is another schematic perspective view of the ultrasonic transducer according to the present disclosure;

FIG. 3 is a schematic cross-sectional view of the ultrasonic transducer in a Y-Z plane according to a first embodiment of the present disclosure;

FIG. 4 is a partial schematic enlarged view of the ultrasonic transducer according to the first embodiment of the present disclosure;

FIG. 5 is a partial schematic enlarged view of another implementation of the ultrasonic transducer according to the first embodiment of the present disclosure;

FIG. 6 is a schematic cross-sectional view of the ultrasonic transducer in a Y-Z plane according to a second embodiment of the present disclosure;

FIG. 7 is a partial schematic enlarged view of the ultrasonic transducer according to the second embodiment of the present disclosure;

FIG. 8 is a partial schematic enlarged view of another implementation of the ultrasonic transducer according to the second embodiment of the present disclosure; and

FIG. 9 is a partial schematic enlarged view of yet another implementation of the ultrasonic transducer according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

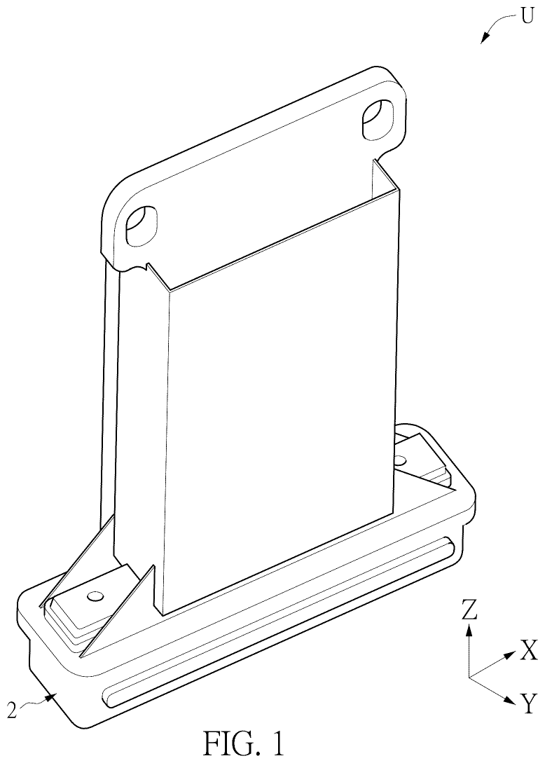

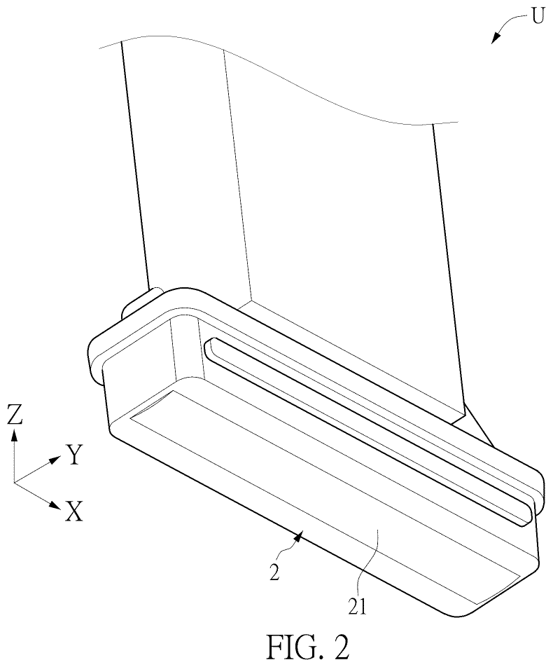

Reference is made to FIGS. 1 and 2. FIGS. 1 and 2 are schematic perspective views of an ultrasonic transducer according to the present disclosure. The present disclosure provides an ultrasonic transducer U that is capable of transmitting and receiving an ultrasonic wave. Generally, the ultrasonic wave is applicable at frequencies above 20,000 Hz, but the frequency range applicable to the ultrasonic transducer U is not limited in the present disclosure.

### First Embodiment

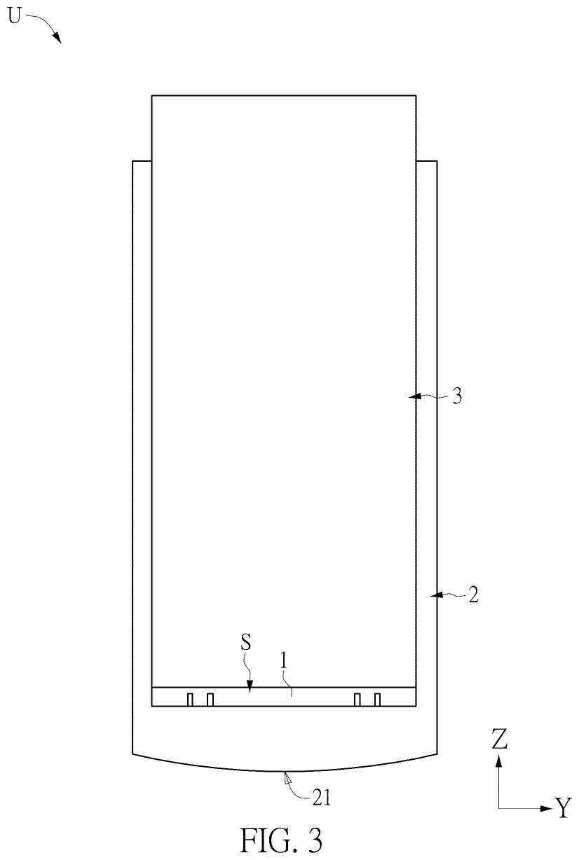

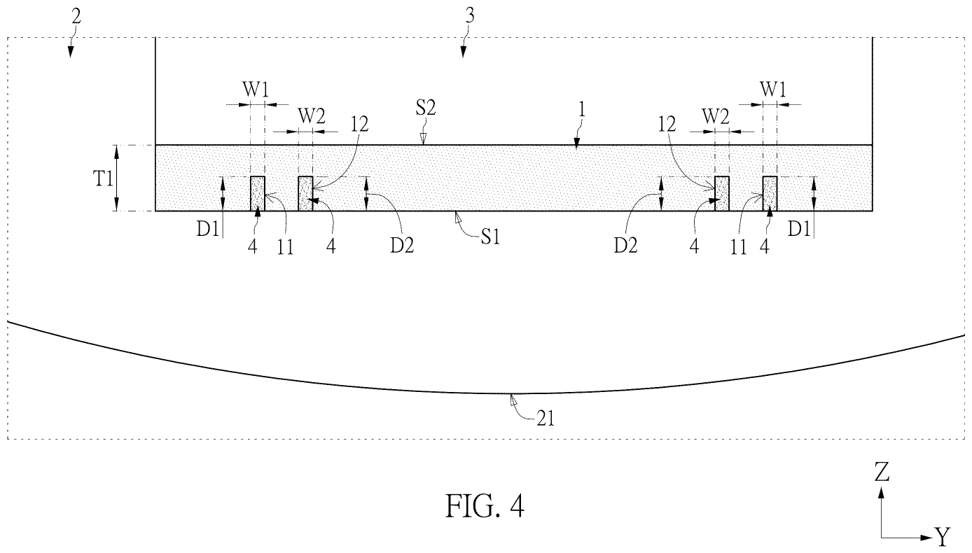

Reference is made to FIGS. 3 and 4. FIG. 3 is a schematic cross-sectional view of the ultrasonic transducer in a Y-Z plane according to a first embodiment of the present disclosure. FIG. 4 is a partial schematic enlarged view of the ultrasonic transducer according to the first embodiment of the present disclosure.

The ultrasonic transducer U includes an energy conversion layer S including a piezoelectric material layer 1, an acoustic lens layer 2, and a backing material layer 3. The energy conversion layer S has a first surface S1 and a second surface S2 that are opposite to each other. The acoustic lens layer 2 is disposed on the first surface S1, and the backing material layer 3 is disposed on the second surface S2. In the first embodiment, the energy conversion layer S is the piezoelectric material layer 1, and the first surface S1 and the second surface S2 are two opposite surfaces of the piezoelectric material layer 1.

For example, the piezoelectric material layer 1 can be made of PZT piezoelectric ceramic. The acoustic lens layer 2, also referred to as an acoustic lens, is a convex lens that can be made of epoxy resin. The material of the piezoelectric material layer 1 and the acoustic lens layer 2 are not limited in the present disclosure. The acoustic lens layer 2 has a curved surface 21 on a side thereof facing the external environment. As shown in FIG. 4, which is an enlarged view of the curved surface 21 of the energy conversion layer S and the acoustic lens layer 2 in FIG. 3. The first surface S1 of the energy conversion layer S (i.e., the piezoelectric material layer 1) faces the curved surface 21, and the second surface S2 of the energy conversion layer S faces away from the curved surface 21. Specifically, the curved surface 21 is a convex curved surface structure (see FIG. 2). When the ultrasonic transducer U is operated by a user, the curved surface 21 contacts a human body, and the piezoelectric material layer 1 is energized to vibrate and generate the ultrasonic wave with a center frequency. The ultrasonic wave passes through the acoustic lens layer 2 and enters the human body to perform image recognition and object detection.

In the present disclosure, a radius of curvature of the curved surface 21 is a circular radius. Through the design of the curved surface 21, the ultrasonic wave is emitted along a radial direction of the curved surface 21, such that ultrasonic energy can be distributed uniformly. In addition, an area of the curved surface 21 is designed to be greater than or equal to an area of the piezoelectric material layer 1. That is, an area of an orthogonal projection of the curved surface 21 of the acoustic lens layer 2 that is projected onto the first surface S1 is greater than or equal to an area of the first surface 21. In the present disclosure, since the area of the curved surface 21 is greater than or equal to the area of the piezoelectric material layer 1, the curved surface 21 completely covers the first surface S1.

For example, the backing material layer 3 can be a composite material composed of polymer resin mixed with conductive powder. However, the material of the backing material layer 3 is not limited in the present disclosure. The backing material layer 3 is used to absorb the ultrasonic wave that is emitted in a reverse direction (i.e., the ultrasonic wave being transmitted in a direction toward the backing material layer 3), such that the reverberation can be reduced to prevent signal interpretation issues caused by interference with the forward-propagating sound field.

Reference is further made to FIGS. 3 and 4. The piezoelectric material layer 1 includes a first groove 11 and a second groove 12. The first groove 11 and the second groove 12 extend in a first direction (i.e., a Z-axis direction) and are oriented toward the acoustic lens layer 2. In addition, the curved surface 21 of the acoustic lens layer 2 extends in a second direction (i.e., a Y-axis direction). The first direction is parallel to a thickness direction of the piezoelectric material layer 1, and the second direction is parallel to a width direction of the piezoelectric material layer 1.

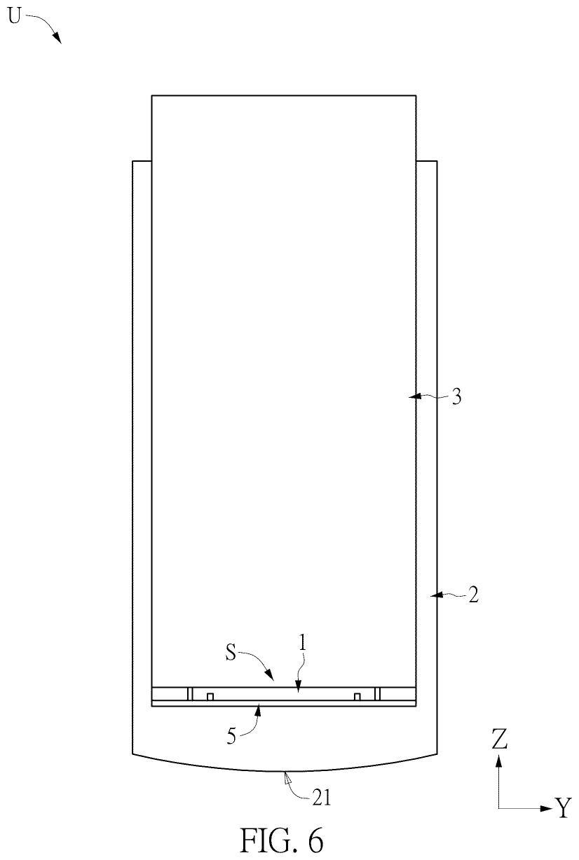

In the present disclosure, quantities of the first groove 11 and second groove 12 can be plural, but the present disclosure is not limited thereto. For example, as shown in FIG. 4 (and FIG. 6 described later), two first grooves 11 and two second grooves 12 are provided. Furthermore, in the present disclosure, the first grooves 11 and the second grooves 12 are completely filled with a filling material 4. The filling material 4 can be, for example, an insulating material. When parts of the piezoelectric material layer 1 are removed to form the first grooves 11 and the second grooves 12, the structural strength of the entire layer is affected. Therefore, by filling the grooves with the filling material 4, the structural strength of the piezoelectric material layer 1 can be enhanced.

Moreover, the first grooves 11 and the second grooves 12 can be designed to penetrate or to not penetrate through the piezoelectric material layer 1. As shown in FIG. 4, both the first grooves 11 and the second grooves 12 do not penetrate the piezoelectric material layer 1. That is, depths of the first grooves 11 and the second grooves 12 are less than a thickness T1 of the piezoelectric material layer 1. For example, the depth D1 of each of the first grooves 11 in the first direction ranges from 1% to 70% of the thickness T1 of the piezoelectric material layer 1. Likewise, the depth D2 of each of the second grooves 12 ranges from 1% to 70% of the thickness T1 of the piezoelectric material layer 1. It should be noted that the thickness T1 of the piezoelectric material layer 1 is approximately one-half wavelength of the center frequency of the ultrasonic wave.

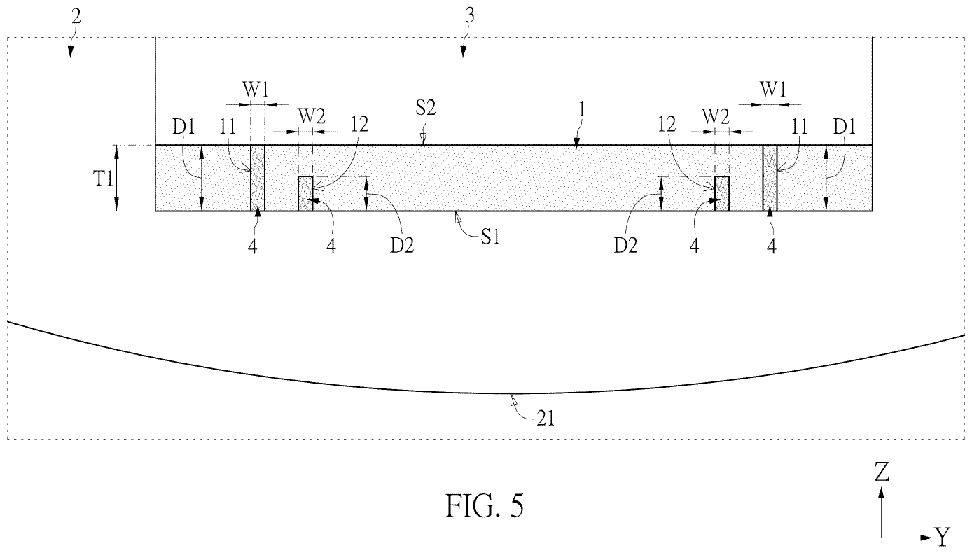

Referring to FIG. 5, which is a partial schematic enlarged view of another implementation of the ultrasonic transducer according to the first embodiment of the present disclosure. As shown in FIG. 5, each of the first grooves 11 penetrates through the piezoelectric material layer 1. That is, the depth D1 of each of the first grooves 11 is equal to the thickness T1 of the piezoelectric material layer 1. Although the second grooves 12 in FIG. 5 do not penetrate the piezoelectric material layer 1, the second grooves 12 in other embodiments can also be designed to penetrate the piezoelectric material layer 1.

Furthermore, regarding the width design of the grooves, a width W1 of each of the first grooves 11 ranges between one-quarter wavelength and one-thirtieth wavelength of the center frequency. Likewise, a width W2 of each of the second grooves 12 ranges between one-quarter wavelength and one-thirtieth wavelength of the center frequency.

### Second Embodiment

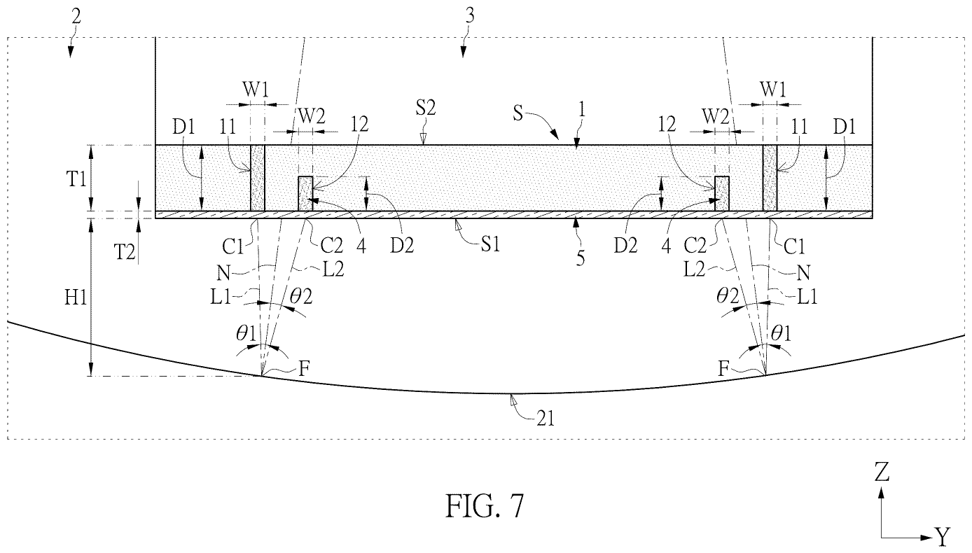

Reference is made to FIGS. 6 and 7. FIG. 6 is a schematic cross-sectional view of the ultrasonic transducer in a Y-Z plane according to a second embodiment of the present disclosure. FIG. 7 is a partial schematic enlarged view of the ultrasonic transducer according to the second embodiment of the present disclosure. Specifically, FIG. 7 enlarges the curved surface 21 of the energy conversion layer S and the acoustic lens layer 2 shown in FIG. 6. The ultrasonic transducer U provided in the second embodiment of the present disclosure has a structure similar to that of the first embodiment. The main difference between the first embodiment and the second embodiment resides in that, in the second embodiment, the energy conversion layer S includes not only the piezoelectric material layer 1, but also a matching layer 5.

The arrangement of the matching layer 5 may be determined according to different application scenarios. For instance, in underwater sonar applications, the ultrasonic transducer generally does not include the matching layer, but instead utilizes the acoustic lens layer for impedance matching. In contrast, in medical applications, the ultrasonic transducer typically incorporates one or more matching layers for impedance matching. A quantity of matching layers 5 is not limited in the present disclosure.

In the second embodiment, the ultrasonic transducer U includes the energy conversion layer S, the acoustic lens layer 2, and the backing material layer 3. The energy conversion layer S includes the piezoelectric material layer 1 and the matching layer 5. Similar to the first embodiment, the piezoelectric material layer 1 in the second embodiment includes the first grooves 11 and the second grooves 12, and both the first grooves 11 and the second grooves 12 are completely filled with the filling material 4.

For example, the matching layer 5 can be made of a composite material composed of polymer resin and hollow particles. However, the material of the matching layer 5 is not limited in the present disclosure. The matching layer 5 is disposed between the piezoelectric material layer 1 and the acoustic lens layer 2, while the piezoelectric material layer 1 is disposed between the matching layer 5 and the backing material layer 3. Accordingly, the first surface S1 of the energy conversion layer S is the surface of the matching layer 5, and the first surface S1 faces the curved surface 21 of the acoustic lens layer 2. The second surface S2 of the energy conversion layer S is the surface of the piezoelectric material layer 1, and the second surface S2 faces away from the curved surface 21.

The arrangement of the matching layer 5 can reduce the reflection of the ultrasonic wave during transmission and improve energy transmission efficiency. The matching layer 5 has a thickness T2 in the first direction, and the thickness T2 is an odd multiple of one-quarter wavelength of the center frequency of the ultrasonic wave. When the thickness T2 of the matching layer 5 is designed to be the odd multiple of one-quarter wavelength of the center frequency, the ultrasonic energy can be efficiently transmitted to pass through the matching layer 5.

In the second embodiment, the first grooves 11 and the second grooves 12 can be designed to penetrate or to not penetrate the piezoelectric material layer 1. For example, in FIG. 7, the first grooves 11 are designed to penetrate the piezoelectric material layer 1. That is, the depth D1 of each of the first grooves 11 in the first direction is equal to the thickness T1 of the piezoelectric material layer 1. The second grooves 12 are designed to not penetrate the piezoelectric material layer 1. That is, the depth D2 of each of the second grooves 12 in the first direction is less than the thickness T1. For instance, the depth D2 ranges from 1% to 70% of the thickness T1.

Additionally, the width W1 of each of the first grooves 11 ranges between one-quarter wavelength and one-thirtieth wavelength of the center frequency. Similarly, the width W2 of each of the second grooves 12 ranges between one-quarter wavelength and one-thirtieth wavelength of the center frequency.

The following describes the design method for determining the positions and dimensions of the grooves (i.e., the first groove 11 and the second groove 12) in the piezoelectric material layer 1. It should be noted that the following description takes the second embodiment shown in FIG. 7 as an example. However, the same design method is applicable to the first embodiment shown in FIGS. 4 and 5.

As shown in FIG. 7, the ultrasonic wave generated from the vibration of the piezoelectric material layer 1 enters into the acoustic lens layer 2 from the first surface S1 of the energy conversion layer S. Since the acoustic lens layer 2 has a curved surface 21, the thicknesses of the acoustic lens layer 2 vary along the second direction. When the ultrasonic wave passes through portions of the acoustic lens layer 2 having a thickness that is an integer multiple of one-quarter wavelength of the center frequency, the ultrasonic wave can pass entirely through the acoustic lens layer 2, in a manner similar to the principle for passing through the matching layer 5.

On the other hand, when the ultrasonic wave passes through the portions of the acoustic lens layer 2 having a thickness that is an integer multiple of one-half wavelength of the center frequency, the ultrasonic energy is reflected back at the curved surface 21 and becomes noise, thereby resulting in a sidelobe effect.

Since the center frequency of the ultrasonic wave is the frequency at which most of the energy is generated, the center frequency is utilized to identify the portions of the acoustic lens layer 2 having a thickness equal to an integer multiple of one-half wavelength. When the ultrasonic wave is transmitted toward these portions, it is mostly reflected back to the piezoelectric material layer 1. Accordingly, the first grooves 11 are formed by removing material from the piezoelectric material layer 1 at positions corresponding to the regions of the acoustic lens layer 2 having a thickness equal to an integer multiple of one-half the wavelength of the center frequency, thereby ensuring that no ultrasonic wave is transmitted toward these regions of the acoustic lens layer 2 and preventing noise generation. Additionally, in consideration of the sensitivity of the ultrasonic transducer, a partial removal approach can be adopted, in which a small portion of the piezoelectric material layer 1 is retained. For example, 1% to 70% of the thickness T1 of the piezoelectric material layer 1 can be removed to reduce the energy generated from the sidelobes. In this way, the noise caused by the sidelobes can be effectively suppressed while maintaining sensitivity.

If the ultrasonic wave has a center frequency of 3.33 MHz and a transmission speed of 1 mm/μs in the acoustic lens layer 2, the wavelength of the ultrasonic wave can be calculated as 0.3 mm, and one-half wavelength is therefore 0.15 mm. Accordingly, by the positions on the piezoelectric material layer 1 that correspond to the regions of the acoustic lens layer 2 having a thickness equal to an integer multiple of 0.15 mm, the positions of the first grooves 11 on the piezoelectric material layer 1 can be determined. As shown in FIG. 7, the first grooves 11 obtained through this design corresponds to first coordinate points C1 on the first surface S1, respectively. The first coordinate points C1 respectively correspond to focal points F on the curved surface 21 along the first direction. Each of the first coordinate points C1 and each of the focal points F have a distance H1 therebetween. As shown in FIG. 7, this distance H1 is equal to the thickness of the acoustic lens layer 2 at that location. Accordingly, the distance H1 is 0.9 mm, which is six times 0.15 mm and thus an integer multiple of one-half wavelength of the center frequency.

In order to further suppress the sidelobe effect, the second grooves 12 are further formed in the piezoelectric material layer 1 to prevent the ultrasonic wave transmitted from the first coordinate points C1 from being reflected back by the curved surface 21 of the acoustic lens layer 2 and received again. In other words, the second grooves 12 are located where the piezoelectric material layer 1 receives the reflected waves from the curved surface 21 of the acoustic lens layer 2.

The positions of the second grooves 12 are designed based on the transmission path of the ultrasonic wave transmitted from the first coordinate points C1 and reflected back at the focal point F. Since the transmission path passes through the portions of the acoustic lens layer 2 with a thickness equal to an integer multiple of one-half wavelength of the center frequency, the ultrasonic wave entering the transmission path are inevitably reflected and becomes noise. As shown in FIG. 6, each of the focal points F is used as a reference point, a normal line N is defined in the radial direction of the curved surface 21, and a first connecting line L1 is defined between each of the first coordinate points C1 and each of the focal points F. The normal line N and the first connecting line L1 have a first angle θ1 therebetween. Based on the principle that the incidence angle is equal to the reflection angle, the second angle θ2 is obtained as the reflection angle corresponding to the first angle θ1 used as the incident angle. A second connecting line L2 is defined based on the second angle θ2. The second angle θ2 is the angle formed between the normal line N and the second connecting line L2. The second connecting line L2 connects the focal point F to one of second coordinate points C2 on the first surface S1. Accordingly, the portions of the piezoelectric material layer 1 corresponding to the second coordinate points C2 are the locations of the second grooves 12.

It should be noted that since the portions of the piezoelectric material layer 1 corresponding to the first coordinate points C1 have been removed to form the first grooves 11, no ultrasonic wave is transmitted from the first coordinate points C1. Nevertheless, the ultrasonic wave reflected from external objects and re-entering the ultrasonic transducer U may still diffuse within the acoustic lens layer 2 and enter the aforementioned transmission path, causing secondary reflections and resulting in noise. Therefore, the second grooves 12 are formed by removing the portions of the piezoelectric material layer 1 corresponding to the second coordinate points C2, thereby preventing the piezoelectric material layer 1 from receiving the reflected ultrasonic wave along the transmission path and eliminating noise.

Furthermore, since the positions of the first grooves 11 correspond to regions of the acoustic lens layer 2 having a thickness equal to an integer multiple of one-half wavelength, and the positions of the second grooves 12 correspond to the reflection location of the ultrasonic wave passing through these regions, the noise received at the second grooves 12 is significantly reduced. Therefore, the portions of the piezoelectric material layer 1 corresponding to the second grooves 12 can be partially removed (i.e., not penetrating the layer) or completely removed (i.e., penetrating the layer).

It should also be noted that the curved surface 21 of the acoustic lens layer 2 is symmetrically designed, so that the portions of the acoustic lens layer 2 having a thickness equal to an integer multiple of one-half wavelength of the center frequency are not limited to a single location but are arranged in pairs. As shown in FIG. 6, there are two locations of the piezoelectric material layer 1 that correspond to portions of the acoustic lens layer 2 having a thickness equal to an integer multiple of one-half wavelength of the center frequency, allowing for the formation of the two first grooves 11. Furthermore, as the piezoelectric material layer 1 becomes wider, or as the acoustic lens layer 2 becomes thinner or designed for higher frequencies, more pairs of the first grooves 11 and the second grooves 12 can be formed.

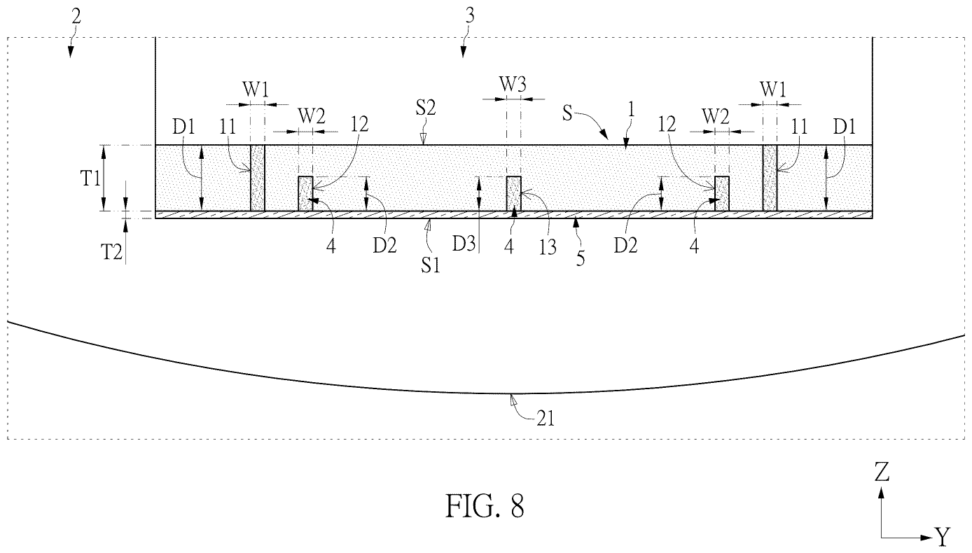

Referring to FIG. 8, which shows another implementation of the ultrasonic transducer according to the second embodiment of the present disclosure. The piezoelectric material layer 1 further includes a third groove 13. The third groove 13 is located at an intermediate position of the piezoelectric material layer 1 in the second direction, and the third groove 13 is completely filled with the filling material 4. The intermediate position of the piezoelectric material layer 1 corresponds to a topmost portion of the curved surface 21, and the topmost portion is essentially planar and parallel to the first surface S1.

As a result, the ultrasonic wave transmitted from the middle region of the piezoelectric material layer 1 is easily reflected back by the topmost portion of the curved surface 21 and becomes noise. Therefore, the noise can be eliminated by removing the central portion of the piezoelectric material layer 1 to form the third groove 13, ensuring that no ultrasonic wave is transmitted from the central portion and reflected by the curved surface 21.

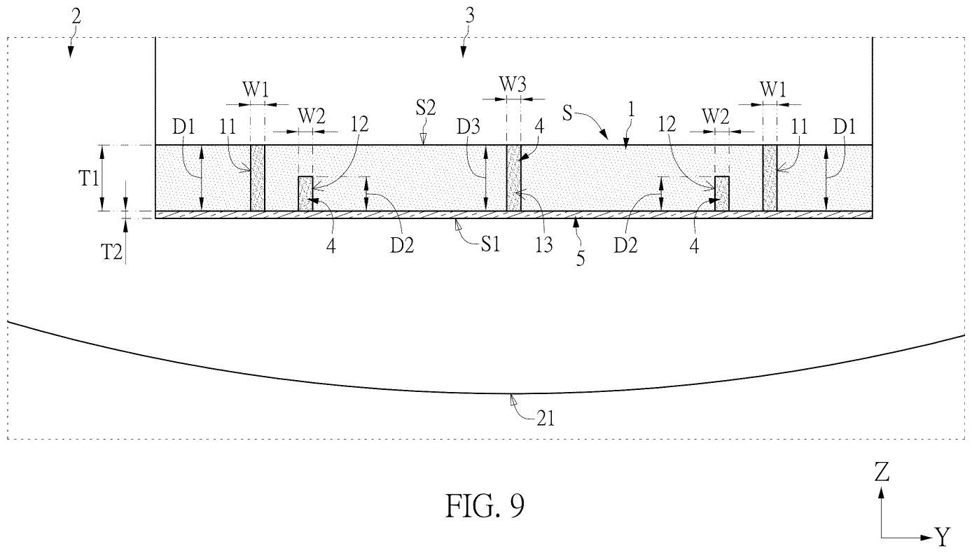

The third groove 13 can be designed to penetrate or to not penetrate the piezoelectric material layer 1. As shown in FIG. 8, the third groove 13 does not penetrate the piezoelectric material layer 1 and has a depth D3 ranging from 1% to 70% of the thickness T1 of the piezoelectric material layer 1 in the first direction. However, referring to FIG. 9, which is a partial schematic enlarged view of yet another implementation of the ultrasonic transducer according to the second embodiment of the present disclosure. The third groove 13 penetrates through the piezoelectric material layer 1 and has a depth D3 equal to the thickness T1 of the piezoelectric material layer 1. In addition, the third groove 13 has a width W3 ranging between one-quarter wavelength and one-thirtieth wavelength of the center frequency.

### Beneficial Effects of the Embodiments

In summary, in the ultrasonic transducer U provided by the present disclosure, the positions in the piezoelectric material layer 1 that correspond to the regions of the acoustic lens layer 2 having a thickness equal to an integer multiple of half the wavelength of the center frequency are identified. The piezoelectric material at these positions is removed to form the first grooves, thereby preventing ultrasonic waves from being transmitted into the regions where the thickness of the acoustic lens layer 2 corresponds to the integer multiple of half the wavelength of the center frequency. As a result, the noise can be eliminated, and the sidelobe effect can be reduced.

Furthermore, in order to further suppress the sidelobe effect, the present disclosure utilizes the principle that the incidence angle is equal to the reflection angle to identify the reflection position corresponding to the center frequency in the piezoelectric material layer 1 and forms the second groove 12 at that location, preventing the reception of the reflected wave caused by the ultrasonic wave transmitted from the first coordinate point C1 and reflected by the curved surface 21 of the acoustic lens layer 2.

Additionally, the noise can be further eliminated by removing the central portion of the piezoelectric material layer 1 to form the third groove 13, ensuring that no ultrasonic wave is transmitted from the central portion and reflected by the curved surface 21.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An ultrasonic transducer for transmitting and receiving an ultrasonic wave,
the ultrasonic transducer comprising:
an energy conversion layer having a first surface and a second surface that are opposite to each other, wherein the energy conversion layer includes a piezoelectric material layer, the piezoelectric material layer has a first groove, the first groove extends along a first direction, and the first direction is parallel to a thickness direction of the piezoelectric material layer; and
an acoustic lens layer disposed on the first surface, wherein the acoustic lens layer has a curved surface, the curved surface extends along a second direction, the second direction is parallel to a width direction of the piezoelectric material layer, and the first groove is oriented toward the acoustic lens layer;
wherein a first coordinate point is defined at a location on the first surface that corresponds to the first groove, the first coordinate point corresponds to a focal point on the curved surface along the first direction, and a distance between the first coordinate point and the focal point is equal to an integer multiple of half a wavelength of a center frequency of the ultrasonic wave.

2. The ultrasonic transducer according to claim 1, wherein the first groove has a depth in the first direction, and the depth of the first groove ranges from 1% to 70% of the thickness of the piezoelectric material layer.

3. The ultrasonic transducer according to claim 1, wherein the first groove penetrates through the piezoelectric material layer along the first direction.

4. The ultrasonic transducer according to claim 1, wherein a width of the first groove ranges between one-quarter wavelength and one-thirtieth wavelength of the center frequency.

5. The ultrasonic transducer according to claim 1, wherein the piezoelectric material layer further has a second groove, and the second groove is oriented toward the acoustic lens layer.

6. The ultrasonic transducer according to claim 5, wherein a second coordinate point is defined at a location on the first surface that corresponds to the second groove, a normal line is defined at the focal point on the curved surface, the first coordinate point and the focal point are connected by a first connecting line, the first connecting line and the normal line have a first angle therebetween, the second coordinate point and the focal point are connected by a second connecting line, the second connecting line and the normal line have a second angle therebetween, and the first angle is equal to the second angle.

7. The ultrasonic transducer according to claim 5, wherein the second groove has a depth in the first direction, and the depth of the second groove ranges from 1% to 70% of the thickness of the piezoelectric material layer.

8. The ultrasonic transducer according to claim 5, wherein the second groove penetrates through the piezoelectric material layer along the first direction.

9. The ultrasonic transducer according to claim 5, wherein a width of the second groove ranges between one-quarter wavelength and one-thirtieth wavelength of the center frequency.

10. The ultrasonic transducer according to claim 5, wherein the piezoelectric material layer further has a third groove, and the third groove is located at an intermediate position of the piezoelectric material layer in the second direction.

11. The ultrasonic transducer according to claim 10, wherein a width of the third groove ranges between one-quarter wavelength and one-thirtieth wavelength of the center frequency.

12. The ultrasonic transducer according to claim 10, wherein the third groove penetrates through the piezoelectric material layer along the first direction.

13. The ultrasonic transducer according to claim 10, wherein the third groove has a depth in the first direction, and the depth of the third groove ranges from 1% to 70% of the thickness of the piezoelectric material layer.

14. The ultrasonic transducer according to claim 10, further comprising a filling material, wherein the filling material completely fills the first groove, the second groove, and the third groove.

15. The ultrasonic transducer according to claim 1, wherein an area of an orthogonal projection of the curved surface of the acoustic lens layer that is projected onto the first surface is greater than or equal to an area of the first surface.

16. The ultrasonic transducer according to claim 1, wherein the energy conversion layer further includes a matching layer, and the matching layer is disposed between the acoustic lens layer and the piezoelectric material layer.

17. The ultrasonic transducer according to claim 16, wherein the matching layer has a thickness in the first direction, and the thickness of the matching layer is equal to one-quarter of the wavelength corresponding to the center frequency.

18. The ultrasonic transducer according to claim 1, further comprising a backing material layer, wherein the backing material layer is disposed on the second surface of the energy conversion layer, and the piezoelectric material layer is disposed between the acoustic lens layer and the backing material layer.
